(19) United States
(12) Patent Application Publication
(10) Pub. No.: US 2015/0268372 A1
(43) Pub. Date: Sep. 24, 2015

(54) METHOD AND APPARATUS FOR DETERMINING FORMATION PROPERTIES USING COLLOCATED TRIAXIAL ANTENNAS WITH NON-PLANAR SINUSOIDAL COILS

(71) Applicant: SCHLUMBERGER TECHNOLOGY CORPORATION, Sugar Land, TX (US)

(72) Inventors: ANDREI I. DAVYDYCHEV, SUGAR LAND, TX (US); GERALD N. MINERBO, MISSOURI CITY, TX (US)

(73) Assignee: SCHLUMBERGER TECHNOLOGY CORPORATION, Sugar Land, TX (US)

(21) Appl. No.: 14/220,874

(22) Filed: Mar. 20, 2014

(51) Int. Cl. G01V 3/28; G01R 1/18

(52) U.S. Cl. CPC G01V 3/28; G01R 1/18

(57) ABSTRACT

A logging tool for use in a wellbore is disclosed herein. The logging tool may include a hollow body. Two or more antenna coils may be disposed at least partially within the body and be axially aligned with one another with respect to a longitudinal axis through the body. Each of the two or more antenna coils, in an unrolled view, may have the form of a sinusoidal function that includes a harmonic of order greater than one.

### BACKGROUND

The present disclosure relates generally to the field of well logging and, more particularly, to the determination of subsurface formation parameters using electromagnetic measurements acquired by an electromagnetic logging tool.

This section is intended to introduce the reader to various aspects of art that may be related to various aspects of the subject matter described and/or claimed below. This discussion is believed to be helpful in providing the reader with background information to facilitate a better understanding of the various aspects of the present disclosure. Accordingly, it should be understood that these statements are to be read in this light, not as admissions of prior art.

Logging tools have long been used in wellbores to make, for example, formation evaluation measurements, which are used to infer properties of the formations surrounding the wellbore and the fluids in the formations. Common logging tools include electromagnetic (resistivity) tools, nuclear tools, acoustic tools, and nuclear magnetic resonance (NMR) tools, though various other types of tools for evaluating formation properties are also available. Early logging tools were run into a wellbore on a wireline cable after the wellbore had been drilled.

Modern versions of such wireline tools are still used extensively. However, as the demand for information while drilling a borehole continued to increase, measurement-while-drilling (MWD) tools and logging-while-drilling (LWD) tools have since been developed. MWD tools generally provide drilling parameter information such as weight on the bit, torque, temperature, pressure, direction, and inclination. LWD tools provide formation evaluation measurements such as resistivity, porosity, NMR distributions, and so forth. MWD and LWD tools often have characteristics common to wireline tools (e.g., transmitting and receiving antennas, sensors, etc.), but are designed and constructed to endure and operate in the harsh environment of drilling.

Electromagnetic measurements are commonly used in downhole applications, such as logging-while-drilling and well logging applications. For example, electromagnetic measurements may be used to determine a subterranean formation resistivity (including horizontal resistivity (Rh) and vertical resistivity (Rv)), formation dip, azimuth, as well as detection of bed boundaries. Further, sometimes alone or in conjunction with other formation measurements (such as porosity), electromagnetic measurements may be used to indicate the presence of hydrocarbons in the formation.

Non-directional tools often refer to those that use antenna coils having magnetic moments that are parallel with the tool axis (sometimes referred to as a z-direction), and are sometimes referred to as axial antenna coils. Non-directional measurements are sometimes also referred to as “conventional” electromagnetic measurements. In low angle and vertical wells, non-directional resistivity measurements are mostly sensitive to Rh, with no or slight sensitivity to Rv. However, in high angle and horizontal wells, non-directional electromagnetic measurements are sensitive to Rh, Rv, and formation dip. Moreover, in a homogenous formation, Rv and dip are coupled, meaning that different pairs of Rv and dip values may produce the same z-z coupling response for a given axial transmitter and axial receiver pair. In such situations, non-directional resistivity measurements do not give enough information to determine Rh and Rv, even when the dip angle is known.

More recently, directional resistivity tools have been developed that make use of tilted or transverse antenna coils (antenna coils that have a magnetic moment that is tilted or transverse with respect to the tool axis). A transverse antenna coil generates a magnetic moment that is perpendicular to the tool axis (by convention the x- or y-direction). A tilted antenna coil is one whose magnetic moment is neither parallel nor perpendicular to the longitudinal axis of the tool. Electromagnetic measurements made by transverse or tilted antenna coils may be referred to as directional measurements. Such a directional arrangement produces a sensitivity on one azimuthal side of the logging tool, which enables the tool to better detect bed boundaries and other features of the subterranean formations to be identified and located. As such, when compared to conventional/non-directional resistivity measurements, directional resistivity responses may be better suited to determine formation characteristics in high-angle or horizontal wells.

Antenna shields are oftentimes used to provide mechanical protection for the antenna coils disposed therein. The shields are generally in the form of a hollow metallic cylinder having a plurality of slots formed therethrough. The slots are oriented perpendicular to the portion of the antenna coil closest thereto. However, when two or more antenna coils are “collocated” in that they are positioned at the same axial location within the tool, the perpendicular orientation of the slots with respect to the antenna coils may cause the slots to intersect, causing mechanical instability in the shield and/or sections (e.g., islands) being altogether removed from the shield.

Accordingly, it would be particularly useful to provide an improved antenna coil design and corresponding shield that provides greater mechanical stability.

### SUMMARY

A summary of certain embodiments disclosed herein is set forth below. It should be understood that these aspects are presented merely to provide the reader with a brief summary of certain embodiments and that these aspects are not intended to limit the scope of this disclosure. Indeed, this disclosure may encompass a variety of aspects that may not be set forth in this section.

A logging tool for use in a wellbore is disclosed. The logging tool may include a hollow body. Two or more antenna coils may be disposed at least partially within the body that is axially aligned with one another with respect to a longitudinal axis through the body. Each of the two or more antenna coils, in an unrolled view, may have the form of a sinusoidal function that includes a harmonic of order greater than one.

In another embodiment, the logging tool may include a hollow metallic body having a plurality of first slots formed radially therethrough. A longitudinal axis through each of the first slots may be parallel to a longitudinal axis through the body. Two or more antenna coils may be disposed at least partially within the body and be axially aligned with one another with respect to the longitudinal axis through the body. Each of the two or more antenna coils, in an unrolled view, may have the form of a sinusoidal function that includes a harmonic of order greater than one causing at least one winding of each of the two or more antenna coils to include three or more zero-derivative points. The longitudinal axis through each of the first slots may be perpendicular to a closest one of the three or more zero-derivative points positioned radially-inward therefrom.

A method for constructing or manufacturing a logging tool for use in a wellbore is also disclosed. The method may include forming two or more antenna coils that, in an unrolled view, have the form of sinusoidal functions that include harmonics of order greater than one. A hollow body may be placed at least partially around the two or more antenna coils such that the two or more antenna coils are axially aligned with one another with respect to a longitudinal axis through the body.

Again, the brief summary presented above is intended to familiarize the reader with certain aspects and contexts of embodiments of the present disclosure without limitation to the claimed subject matter.

### BRIEF DESCRIPTION OF THE DRAWINGS

Other aspects and advantages of the invention will become apparent upon reading the following detailed description and upon reference to the drawings in which:

FIG. 1 depicts a schematic side view of an illustrative well site system including a drill string and a bottom hole assembly disposed within a wellbore, according to one or more embodiments disclosed.

FIG. 2 depicts a perspective view of an electromagnetic logging tool including three illustrative collocated tilted antenna coils, according to one or more embodiments disclosed.

FIG. 3 depicts an unrolled view of the three antenna coils from FIG. 2, according to one or more embodiments disclosed.

FIG. 4 depicts a perspective view of another electromagnetic logging tool including three illustrative collocated tilted antenna coils that include harmonics up to order five, according to one or more embodiments disclosed.

FIG. 5 depicts an unrolled view of the three antenna coils from FIG. 4, according to one or more embodiments disclosed.

FIG. 6 depicts a perspective view of another electromagnetic logging tool including three illustrative collocated tilted antenna coils that include harmonics up to order seven, according to one or more embodiments disclosed.

FIG. 7 depicts an unrolled view of the three antenna coils from FIG. 6 shown in a single plane, according to one or more embodiments disclosed.

FIG. 8 depicts an unrolled view of the three antenna coils shown in FIG. 5 with a plurality of illustrative vertical slots formed in a shield and positioned at the zero-derivative locations of the antenna coils, according to one or more embodiments disclosed.

FIG. 9 depicts an unrolled view of the three antenna coils and the vertical slots from FIG. 8 where the vertical slots have been partitioned into shorter portions, according to one or more embodiments disclosed.

FIG. 10 depicts an unrolled view of the three antenna coils and the vertical slots from FIG. 9 and also including a plurality of tilted slots, according to one or more embodiments disclosed.

### DETAILED DESCRIPTION

One or more specific embodiments of the present disclosure are described below. These embodiments are merely examples of the presently disclosed techniques. Additionally, in an effort to provide a concise description of these embodiments, all features of an actual implementation may not be described in the specification. It should be appreciated that in the development of any such implementation, as in any engineering or design project, numerous implementation-specific decisions are made to achieve the developers' specific goals, such as compliance with system-related and business-related constraints, which may vary from one implementation to another. Moreover, it should be appreciated that such development efforts might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The embodiments discussed below are intended to be examples that are illustrative in nature and should not be construed to mean that the specific embodiments described herein are necessarily preferential in nature. Additionally, it should be understood that references to “one embodiment” or “an embodiment” within the present disclosure are not to be interpreted as excluding the existence of additional embodiments that also incorporate the recited features. Further, as used herein, the terms “inner” and “outer;” “up” and “down;” “upper” and “lower;” “upward” and “downward;” “above” and “below;” “inward” and “outward;” and other like terms as used herein refer to relative positions to one another and are not intended to denote a particular direction or spatial orientation. The terms “couple,” “coupled,” “connect,” “connection,” “connected,” “in connection with,” and “connecting” refer to “in direct connection with” or “in connection with via another element or member.”

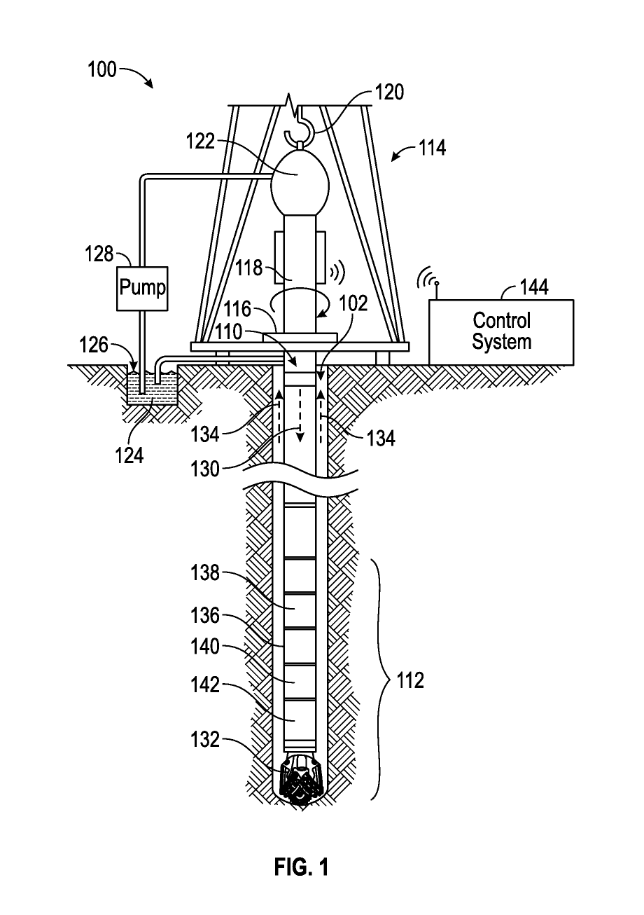

FIG. 1 depicts a schematic side view of an illustrative well site system 100 including a drill string 110 and a bottom hole assembly (BHA) 112 disposed within a wellbore 102, according to one or more embodiments disclosed. The well site system 100 may be deployed in either onshore or offshore applications. In this type of system, the wellbore 102 may be formed in subsurface formations by rotary drilling in a manner that is well-known to those skilled in the art. Some embodiments may also use directional drilling.

The drill string 110 may be suspended within the wellbore 102. The well site system 100 may include a platform and derrick assembly 114 positioned over the wellbore 102, with the derrick assembly 114 including a rotary table 116, a kelly 118, a hook 120, and a rotary swivel 122. In a drilling operation, the drill string 110 may be rotated by the rotary table 116, which engages the kelly 118 at the upper end of the drill string 110. The drill string 110 may be suspended from the hook 120, attached to a traveling block (also not shown), through the kelly 118 and the rotary swivel 122, which permits rotation of the drill string 110 relative to the hook 120. As is well-known, a top drive system may be used in other embodiments.

Drilling fluid or mud 124 may be stored in a pit 126 formed at the well site. A pump 128 may deliver the drilling fluid 124 to the interior of the drill string 110 via a port in the swivel 122, which causes the drilling fluid 124 to flow downwardly through the drill string 110, as indicated by the directional arrow 130. The drilling fluid exits the drill string 110 via ports in a drill bit 132, and then circulates upwardly through the annulus region between the outside of the drill string 110 and the wall of the wellbore 102, as indicated by the directional arrows 134. In this known manner, the drilling fluid lubricates the drill bit 132 and carries formation cuttings up to the surface as it is returned to the pit 126 for recirculation.

In the illustrated embodiment, the BHA 112 is shown as having a measurement-while-drilling module (MWD) module 136 and multiple logging-while-drilling (LWD) modules 138, 140. As used herein, the term “module” as applied to MWD and LWD devices is understood to mean either a single tool or a suite of multiple tools contained in a single modular device. Additionally, the BHA 112 may include a rotary steerable system (RSS), a motor 142, and the drill bit 132.

The LWD modules 138, 140 may be housed in a drill collar and may include one or more types of logging tools. The LWD modules 138, 140 may be able to measure, process, and store information, as well as communicate with the surface equipment. By way of example, the LWD modules 138, 140 may include an electromagnetic logging tool. The electromagnetic logging tool may include transmitter and/or receiver antenna coils for acquisition of electromagnetic measurements. In at least one embodiment, the electromagnetic logging tool includes the capability to make non-directional and/or directional electromagnetic measurements (e.g., one or more of its transmitter and/or receiver antenna coils may be tilted or transverse with respect to the central longitudinal axis of the BHA 112).

In operation, the well site system 100 may be controlled using a control system 144 located at the surface. The control system 144 may include one or more processor-based computing systems. In the present context, a processor may include a microprocessor, programmable logic devices (PLDs), field-gate programmable arrays (FPGAs), application-specific integrated circuits (ASICs), system-on-a-chip processors (SoCs), or any other suitable integrated circuit capable of executing encoded instructions stored, for example, on tangible computer-readable media (e.g., read-only memory, random access memory, a hard drive, optical disk, flash memory, etc.). Such instructions may correspond to, for instance, workflows and the like for carrying out a drilling operation, algorithms and routines for processing data received at the surface from the BHA 112 (e.g., as part of an inversion to obtain one or more desired formation parameters), and so forth.

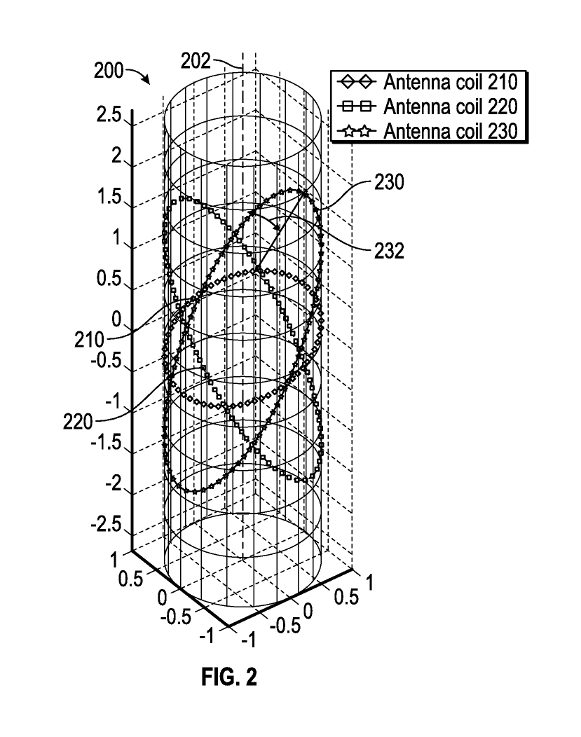

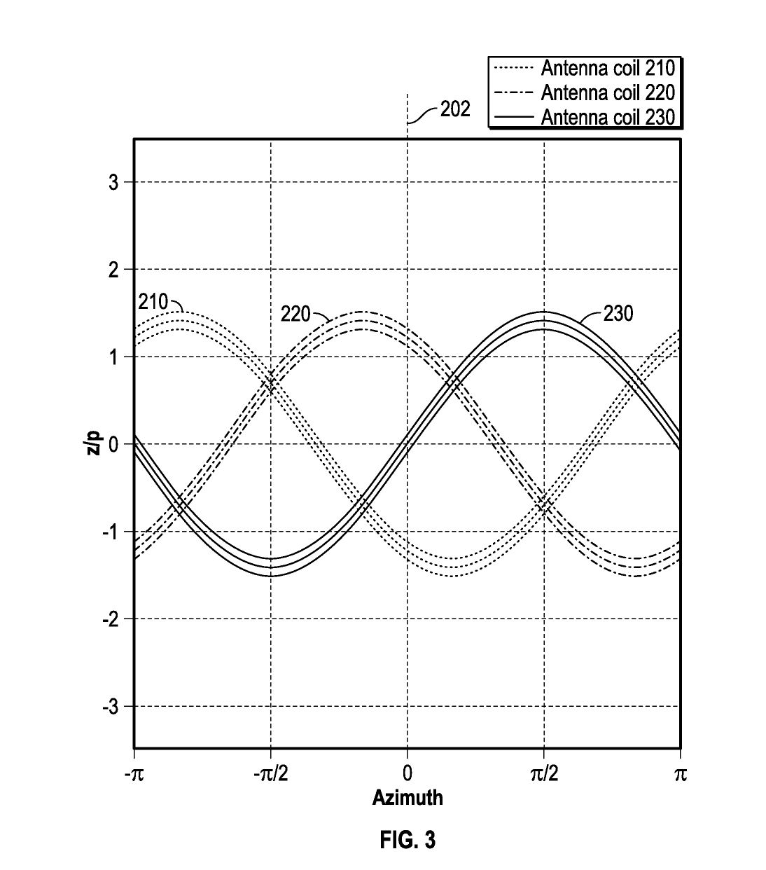

FIG. 2 depicts a perspective view of an electromagnetic logging tool 200, which may be disposed within the LWD module 138 (of FIG. 1) and includes three illustrative collocated tilted antenna coils 210, 220, 230, according to one or more embodiments disclosed. FIG. 3 depicts an unrolled view of the three antenna coils 210, 220, 230 from FIG. 2, according to one or more embodiments disclosed. The planar tilted coils 210, 220, 230 have an unrolled view (as described below) that involves the first-harmonic sinusoid.

The three coils 210, 220, 230 are identical, except that each is rotated by 120° azimuthally from the neighboring coil 210, 220, 230. Each antenna coil 210, 220, 230 may include one or more windings where each winding extends 360° around the central longitudinal axis 202 of the logging tool 200.

As shown, the azimuthal rotation angles (one is shown, 232) with respect to the central longitudinal axis 202 through the logging tool 200 are 0°, 120°, and 240°. However, as will be appreciated, different values may be selected provided they give three independent directions for the magnetic moments of the three antenna coils 210, 220, 230.

The antenna coils 210, 220, 230 lie on or in a cylindrical surface. The display obtained by flattening this cylindrical surface onto a plane is called an “unrolled” or “unwrapped” view, as shown in FIGS. 3, 5, and 7-10). The antenna coils 210, 220, 230 have a sinusoidal shape when the distance z along the longitudinal axis 202 is plotted as a function of the azimuthal angle φ (sin φ). The angle φ is measured in the plane perpendicular to the longitudinal axis 202. The antenna coils 210, 220, 230 that do not include any higher harmonics, as in FIG. 2, are described by the following equation:

z=ρa₁ sin φ (1)

where ρ is the radius of the cylinder, φ is the azimuth, and 2ρa₁ defines the height of the coil in the z direction (along the tool axis). a₁ is related to the coil tilt angle r through:

a₁=tan τ (2)

A more general periodic dependence is obtained by including higher harmonics:

$$z = ρ {\sum }_{j = 1}^{∞} {a}_{j} sin ( jφ ) \qquad ( 3 )$$

When this series has a finite number of terms (harmonics), this corresponds to aⱼ=0 for j>j₀. To keep the symmetry of the antenna coils 210, 220, 230, the odd harmonics may be considered and the even harmonics disregarded (although for generality, we may include even harmonics as well). The x component of the dipole moment is defined by the coefficient a₁ of the first harmonic. The higher terms will not contribute to the dipole moment.

In this more general case, the projections of the antenna coils 210, 220, 230 onto the (x,z) and (y,z) planes may be described, respectively, as:

$$\begin{matrix}z ( x ) = ρ {\sum }_{j = 1}^{∞} {a}_{j} sin ( j arcsin \frac{x}{ρ} ) , & ( 4 ) \\ z ( y ) = ρ {\sum }_{j = 1}^{∞} {a}_{j} sin ( j arccos \frac{y}{ρ} ) & ( 5 )\end{matrix}$$

For odd harmonics, this gives polynomial dependence z(x)—cubic if the highest harmonic is sin(3φ), quintic if the highest harmonics is sin(5φ), septic if the highest harmonic is sin(7φ), etc., whereas z(y) is ±\sqrt{ρ²−y²} times a polynomial in (y/ρ)². To prove this in a general case, one may use representations of sines and cosines of multiple angles (sin(jφ) and cos(jφ)) in terms of Chebyshev polynomials Tⱼ(sin φ) and Uⱼ₋₁ (sin φ) of sines of the single angle φ.

Note that in the general case, the length of the antenna coils 210, 220, 230 may be evaluated as:

$$𝓁 = ρ {{\int }_{0}}^{2 π} d φ \sqrt{1 + {( {\sum }_{j = 1}^{∞} {a}_{j} j cos ( jφ ) )}^{2}} \qquad ( 6 )$$

As an additional property, we may also consider the convexity of the antenna coils 210, 220, 230, which basically means that the derivative of z(φ) with respect to φ does not change sign between the minimal and the maximal values of z.

If we consider the slot direction (described below) to be perpendicular to the direction of the antenna coil 210, 220, 230, then we get the following general result for the “slot function” \tilde{z}(φ,φ₀):

$$\frac{1}{ρ} \tilde{z} ( φ , {φ}_{0} ) = - {{\int }_{{φ}_{0}}}^{φ} \frac{d φ}{{\sum }_{j = 1}^{∞} {a}_{j} j cos ( j φ )} + {\sum }_{j = 1}^{∞} {a}_{j} sin ( {jφ}_{0} ) \qquad ( 7 )$$

where φ₀ is the predefined angle (azimuthal position), at which a slot crosses the central antenna coil's winding, as described in greater detail below.

Although the antenna coils 210, 220, 230 shown in FIG. 2 include the first harmonic, sin φ, higher order harmonics may be used. Although the following description focuses on odd harmonics, it will be appreciated that even harmonics may be incorporated instead of, or in addition to, the odd harmonics. Similarly, although this disclosure discusses the third harmonic (cubic), the fifth harmonic (quintic), and the seventh harmonic (septic), it may be appreciated that other harmonics may be used instead of, or in addition to, those discussed herein.

The antenna coils 210, 220, 230 may include higher order harmonics. More particularly, the antenna coils 210, 220, 230 may include an nth order harmonic, where n is greater than one (e.g., three or more). For example, if the antenna coil 210, 220, 230 includes a third order harmonic (i.e., cubic antenna coils), the equation is

z=ρ[a₁ sin φ+a₃ sin(3φ)]. (8)

Its projections onto the (x,z) and (y,z) planes, respectively are given by:

$$\begin{matrix}z ( x ) = ( {a}_{1} + 3 {a}_{3} ) x - 4 {a}_{3} \frac{{x}^{3}}{{ρ}^{2}} , & ( 9 ) \\ z ( y ) = \pm \sqrt{{ρ}^{2} - {y}^{2}} [ {a}_{1} - {a}_{3} + 4 {a}_{3} \frac{{y}^{2}}{{ρ}^{2}} ] . & ( 10 )\end{matrix}$$

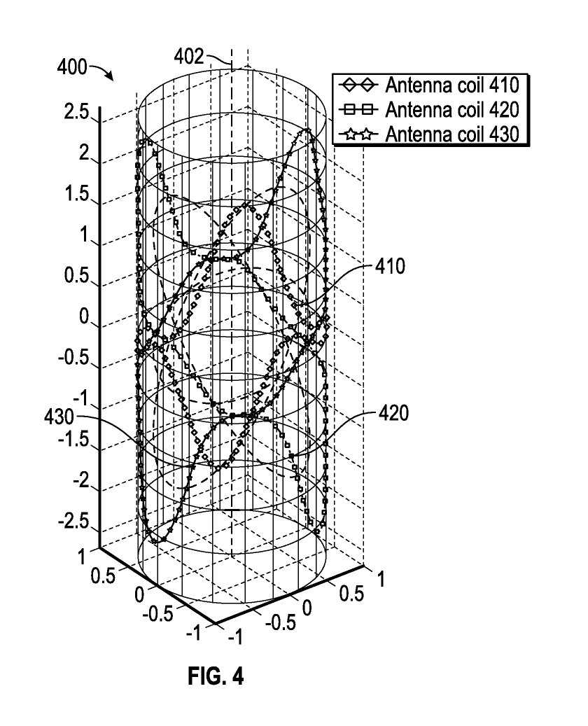

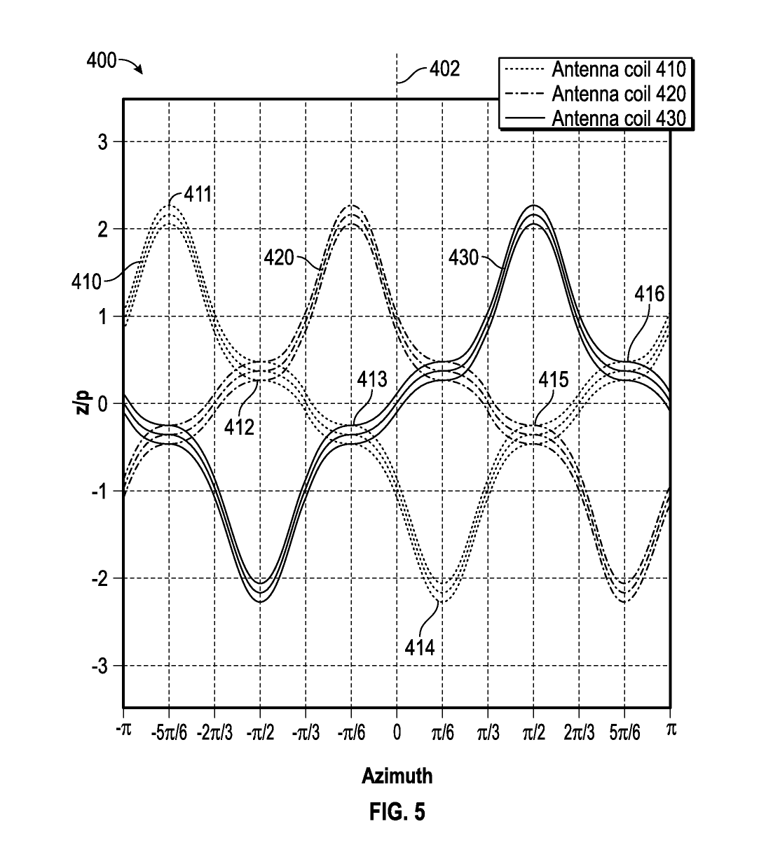

FIG. 4 depicts a perspective view of an electromagnetic logging tool 400 including three illustrative collocated tilted antenna coils 410, 420, 430 that include harmonics through the fifth order (i.e., quintic coils). FIG. 5 depicts an unrolled view of the three antenna coils 410, 420, 430 from FIG. 4, according to one or more embodiments disclosed. The coils 410, 420, 430 considered here lie on a cylindrical surface. In the general case, the equation for the quintic antenna coil 410, 420, 430 is:

z=ρ[a₁ sin φ+a₃ sin(3φ)+a₅ sin(5φ)] (11)

Its projections onto the (x,z) and (y,z) planes, respectively are given by:

$$\begin{matrix}z ( x ) = ( {a}_{1} + 3 {a}_{3} + 5 {a}_{5} ) x - 4 ( {a}_{3} + 5 {a}_{5} ) \frac{{x}^{3}}{{ρ}^{2}} + 16 {a}_{5} \frac{{x}^{5}}{{σ}^{4}} , & ( 12 ) \\ z ( y ) = \pm \sqrt{{ρ}^{2} - {y}^{2}} [ {a}_{1} - {a}_{3} + {a}_{5} + 4 ( {a}_{3} - 3 {a}_{5} ) \frac{{y}^{2}}{{ρ}^{2}} + 16 {a}_{5} \frac{{y}^{4}}{{ρ}^{4}} ] . & ( 13 )\end{matrix}$$

As shown, the antenna coils 410, 420, 430 are axially collocated and azimuthally (or rotationally) offset from one another by 2π/3 (i.e., 120°) about the central longitudinal axis 402 of the logging tool 400. Each winding of each antenna coil 410, 420, 430 includes three or more (six are shown for this quintic embodiment) zero-derivative points 411, 412, 413, 414, 415, 416 that are horizontal (i.e., have a slope of zero with respect to the central longitudinal axis 402 of the logging tool 400). For purposes of simplicity, the zero-derivative points 411-416 for the first antenna coil 410 are labelled. At the zero-derivative points 411-416:

$$\frac{d z}{d φ} = 0 \qquad ( 14 )$$

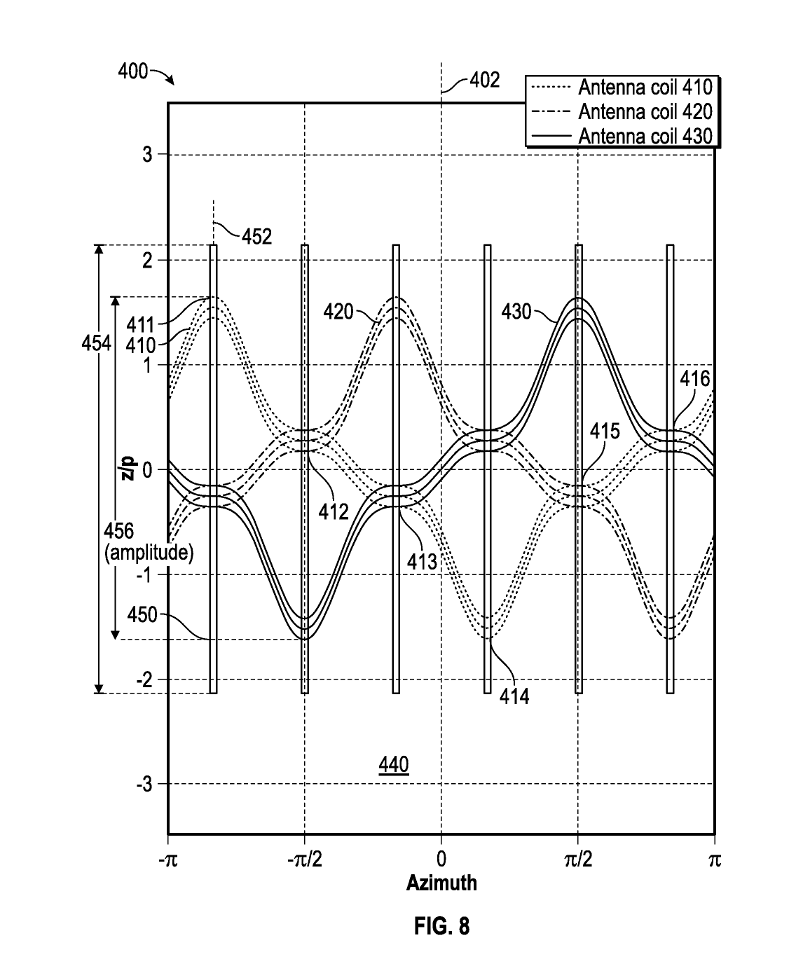

The spacing and/or positioning of the zero-derivative points 411-416 may be based at least partially upon the coefficients a₁, a₃, a₅, etc. The circumferential spacing between adjacent zero-derivative points 411-416 may be the same, or the spacing may be different. For example, in FIGS. 4 and 5, a₃=−(1/3)a₁, and a₅=(1/5)a₁; however, as will be appreciated these coefficients for a, are merely illustrative. As shown, the six zero-derivative points 411-416 for each quintic coil (e.g., coil 410) may be spaced apart by π/3 (i.e., they are offset along the azimuth by 60° from one another). By positioning the three antenna coils 410, 420, 430 offset along the azimuth by 2π/3 (i.e., 120°), the six zero-derivative points 411-416 for each antenna coil (e.g., antenna coil 410) may be vertically aligned with corresponding zero-derivative points of the other two antenna coils (e.g., antenna coils 420, 430). This may be relevant for the placement and orientation of one or more slots, as discussed in more detail with reference to FIGS. 8-10.

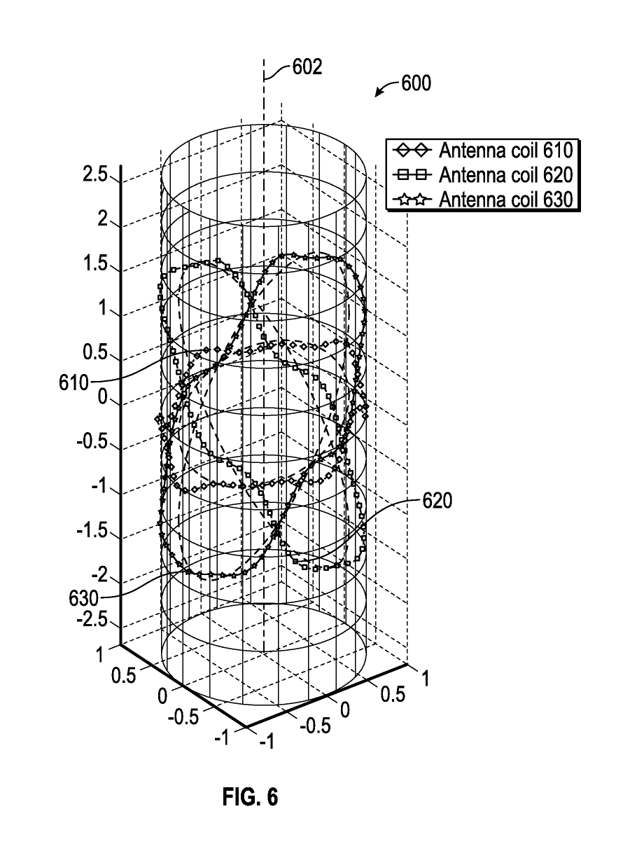

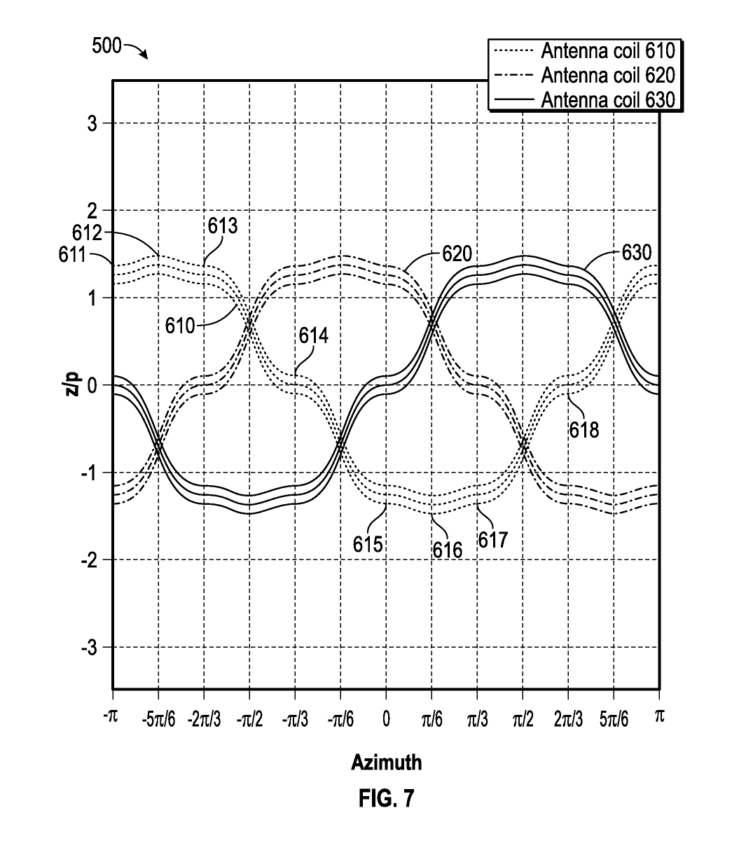

FIG. 6 depicts a perspective view of another electromagnetic logging tool 600 including three illustrative tilted collocated antenna coils 610, 620, 630 that include harmonics up to order seven (i.e., “septic” coils), and FIG. 7 depicts an unrolled view of the three antenna coils 610, 620, 630 from FIG. 6, according to one or more embodiments disclosed. In the general case, the equation for the septic coil 610, 620, 630 is:

z=ρ[a₁ sin φ+a₃ sin(3φ)+a₅ sin(5φ)+a₇ sin(7φ)] (15)

Its projections onto the (x,z) and (y,z) planes, respectively are given by:

$$\begin{matrix}z ( x ) = ( {a}_{1} + 3 {a}_{3} + 5 {a}_{5} + 7 {a}_{7} ) x - 4 ( {a}_{3} + 5 {a}_{5} + 14 {a}_{7} ) \frac{{x}^{3}}{{ρ}^{2}} + 16 ( {a}_{5} + 7 {a}_{7} ) \frac{{x}^{5}}{{ρ}^{4}} - 64 {a}_{7} \frac{{x}^{7}}{{ρ}^{6}} , & ( 16 ) \\ z ( y ) = \pm \sqrt{{ρ}^{2} + {y}^{2}} [ {a}_{1} - {a}_{3} + {a}_{5} - {a}_{7} + 4 ( {a}_{3} - 3 {a}_{5} + 6 {a}_{7} ) \frac{{y}^{2}}{{ρ}^{2}} + 16 ( {a}_{5} - 5 {a}_{7} ) \frac{{y}^{4}}{{ρ}^{4}} + 64 {a}_{7} \frac{{y}^{6}}{{ρ}^{6}} ] . & ( 17 )\end{matrix}$$

Similar to the quintic antenna coils 410, 420, 430 shown in FIGS. 4 and 5, the septic antenna coils 610, 620, 630 shown in FIGS. 6 and 7 are axially collocated and azimuthally (or rotationally) offset from one another by 2π/3 (i.e., 120°) about the central longitudinal axis 602 of the logging tool 600. Each winding of each antenna coil 610, 620, 630 includes three or more (eight are shown for this septic embodiment) zero-derivative points 611, 612, 613, 614, 615, 616, 617, 618 that are horizontal (i.e., have a slope of zero with respect to the central longitudinal axis 602 of the logging tool 600). For purposes of simplicity, the zero-derivative points 611-618 for the first antenna coil 610 are labeled.

As discussed, above, the circumferential spacing between adjacent zero-derivative points 611-618 may be the same, or the spacing may be different (depending at least partially on the coefficients aᵢ). For example, in FIGS. 6 and 7, a₃=0, a₅=−(1/10)a₁, and a₇=(1/14)a₁; however, as will be appreciated these coefficients for a, are merely illustrative. As shown, each of the eight zero-derivative points 611-618 for each septic antenna coil (e.g., coil 610) may not be evenly offset along the azimuth from one another. For example, looking at the first septic coil 610, the zero-derivative points 611-618 occur at −π, −5π/6, −2π/3, −π/3, 0, π/6, π/3, and 2π/3. Thus, some of the adjacent zero-derivative points (e.g., points 611, 612) may be offset along the azimuth by π/6 (30°) while other adjacent zero-derivative points (e.g., points 613, 614) may be offset along the azimuth by π/3 (60°).

By positioning the three antenna coils 610, 620, 630 offset along the azimuth by 2π/3 (i.e., 120°), many of the eight zero-derivative points 611-618 for each antenna coil (e.g., antenna coil 610) may be vertically aligned with corresponding zero-derivative points of the other two antenna coils (e.g., antenna coils 620, 630). As shown, six of the eight zero-derivative points (e.g., points 611, 613, 614, 615, 617, 618) for the first antenna coil 610 may be aligned with corresponding zero-derivative points for the other two antenna coils 620, 630, while two of the zero-derivative points (e.g., points 612, 616) may not be aligned. This may be relevant for the placement and orientation of the slots, as discussed in more detail with reference to FIGS. 8-10.

FIG. 8 depicts an unrolled view of the three (quintic) antenna coils 410, 420, 430 shown in FIG. 5 with a plurality of illustrative first or vertical slots 450 formed in a shield 440 and positioned at the zero-derivative points 411-416 of the antenna coils 410, 420, 430, according to one or more embodiments disclosed. The logging tool 400 may include a shield 440 disposed around the antenna coils 410, 420, 430. The shield 440 may be or include a hollow, cylindrical, metallic body having one or more openings or slots 450 formed radially therethrough. Each of the slots 450 may be vertical (i.e., have a central longitudinal axis 452 that is parallel to the central longitudinal axis 402 of the logging tool 400).

The vertical slots 450 may also be formed or positioned in the shield 440 such that the central longitudinal axes 452 of the vertical slots 450 are perpendicular to a (closest) zero-derivative point 411-416 of one or more of the antenna coils (e.g., coil 410) positioned radially-inward therefrom. The perpendicular orientation between the vertical slots 450 and the (closest) zero-derivative point 411-416 of the antenna coils 410, 420, 430 may allow for a desired radiation pattern to be transmitted and/or received therethrough by the antenna coils 410, 420, 430. Thus, for the quintic antenna coils 410, 420, 430 shown in FIG. 8, the vertical slots 450 may be spaced apart by π/3 around the azimuth of the shield 440 such that each vertical slot 450 may be aligned with a zero-derivative point 411-416 of each of the antenna coils 410, 420, 430.

As shown in FIG. 8, the vertical slots 450 may be axially-aligned (e.g., axially overlap) with one another. Although not shown, in other embodiments, adjacent vertical slots 450 may be axially-offset from one another. For example, the slot 450 at −5π/6 may be shifted slightly upward (as shown on FIG. 8) with respect to the slot 450 at −7π/2 such that the slot 450 at −5π/6 partially (but not completely) axially overlaps with the slot 450 at −7π/2. In another example, the slot 450 at −5π/6 may be shifted further upward (as shown on FIG. 8) with respect to the slot 450 at −7π/2 such that the slot 450 at −5π/6 no longer axially overlaps with the slot 450 at −7π/2. Shifting the position of one or more of the slots 450 may enable the slots 450 to more closely follow the sinusoidal position of the antenna coils 410, 420, 430. The length 454 of the vertical slots 450 may be greater than or equal to the amplitude 456 of the antenna coils 410, 420, 430.

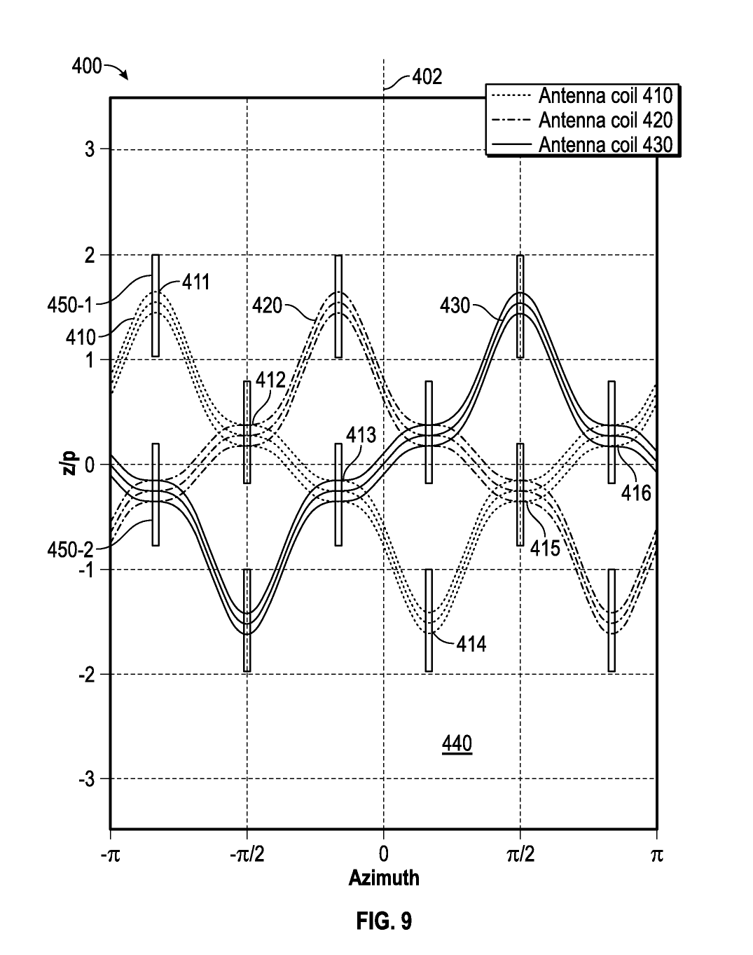

FIG. 9 depicts an unrolled view of the three antenna coils 410, 420, 430 and the vertical slots 450 from FIG. 8 where the vertical slots 450 have been partitioned into shorter portions 450-1, 450-2, according to one or more embodiments disclosed. Each vertical slot 450 shown in FIG. 8 may be divided or partitioned into two or more vertical slots 450-1, 450-2 to reduce the overall length of the slot 450. For example, as shown, the slot 450 has been partitioned into a first or “upper” slot 450-1 and a second or “lower” slot 450-2. The first slot 450-1 may be axially aligned with the zero-derivative point 411 of the antenna coil 410 at −5π/6, and the second slot 450-2 may be axially aligned with the zero-derivative points of the antenna coils 420, 430 at −5π/6. This may leave a gap between the first and second slots 450-1, 450-2.

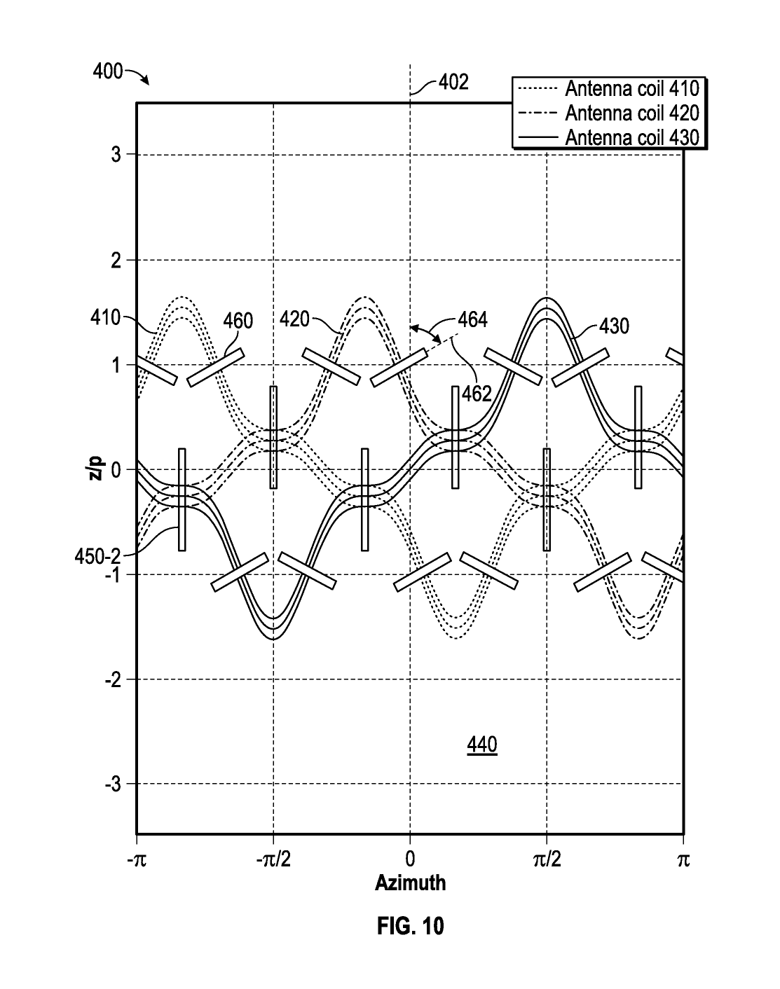

FIG. 10 depicts an unrolled view of the three antenna coils 410, 420, 430 and the vertical slots 450-2 from FIG. 9 (slots 450-1 omitted) and also including a plurality of second or tilted slots 460, according to one or more embodiments disclosed. In addition to the vertical slots 450-2, one or more tilted slots 460 may be formed in the shield 440. As with the vertical slots 450-2, the tilted slots 460 may have a central longitudinal axis 462 that is perpendicular to a (closest) portion of an antenna coil 410, 420, 430 positioned radially-inward therefrom. However, the central longitudinal axis 462 of the tilted slots 460 may not be parallel to the central longitudinal axis 402 of the logging tool 400. Although shown as substantially linear, the vertical slots 450-2 and/or the tilted slots 460 may be curved in other embodiments.

The addition of the tilted slots 460 may improve the dipole moment of the antenna coils 410, 420, 430. For example, when the antenna coils 410, 420, 430 are oriented at an angle of about 45° with respect to the central longitudinal axis 402 of the logging tool 400, the addition of the tilted slots 460 may enable the dipole moment to be closer to the desired 45° than without the tilted slots 460.

In operation, the logging tool 400 (or 600) may be constructed or manufactured by forming two or more antenna coils 410, 420, 430 that, in an unrolled view, are represented by sinusoidal functions that include harmonics of order greater than one. For example, as shown in FIGS. 4 and 5, the sinusoidal functions include fifth order harmonics, and as shown in FIGS. 6 and 7, the sinusoidal functions include seventh order harmonics. Other harmonics or combinations of harmonics are also contemplated.

The antenna coils 410, 420, 430 may be formed on or disposed in the tool body (e.g., on or in a recess of a drill collar). The hollow cylindrical shield 440 may then be placed at least partially over or around the antenna coils 410, 420, 430 such that the two or more antenna coils 410, 420, 430 are axially aligned with one another (i.e., collocated) with respect to the longitudinal axis 402 through the shield 440. The vertical slots 450 may be formed radially through the shield 440. In at least one embodiment, the tilted slots 460 may also be formed radially through the shield 440. The placement of the hollow cylindrical shield 440 over the antenna coils 410, 420, 430 may be done in such a way that slots 450 are aligned with zero-derivative points of the antenna coils 410, 420, 430, as generally depicted in the above-described embodiments, and/or that tilted slots 460 are substantially perpendicular to underlying windings of antenna coils 410, 420, 430.

While the specific embodiments described above have been shown by way of example, it will be appreciated that many modifications and other embodiments will come to the mind of one skilled in the art having the benefit of the teachings presented in the foregoing description and the associated drawings. Accordingly, it is understood that various modifications and embodiments are intended to be included within the scope of the appended claims.

What is claimed is:

1. A logging tool for use in a wellbore, comprising:
a hollow body; and
two or more antenna coils disposed at least partially within the body that are axially aligned with one another with respect to a longitudinal axis through the body, wherein each of the two or more antenna coils, in an unrolled view, has the form of a sinusoidal function that includes a harmonic of order greater than one.

2. The logging tool of claim 1, wherein each of the two or more antenna coils, in the unrolled view, is the sinusoidal function of an azimuthal angle, and wherein the azimuthal angle is measured in a plane that is perpendicular to the longitudinal axis through the body.

3. The logging tool of claim 1, wherein the sinusoidal function includes a third harmonic.

4. The logging tool of claim 1, wherein the sinusoidal function includes a fifth harmonic.

5. The logging tool of claim 1, wherein the sinusoidal function includes a seventh harmonic.

6. The logging tool of claim 1, wherein the two or more antenna coils comprise three antenna coils that are each rotationally-offset from one another by about 120° about the central longitudinal axis through the body.

7. The logging tool of claim 1, wherein the two or more antenna coils comprise tilted antenna coils with respect to the longitudinal axis through the body.

8. The logging tool of claim 1, wherein each of the two or more antenna coils comprises one or more windings, each winding including three or more zero-derivative points.

9. A logging tool for use in a wellbore, comprising:
a hollow metallic body having a plurality of first slots formed radially therethrough, wherein a longitudinal axis through each of the first slots is parallel to a longitudinal axis through the body; and
two or more antenna coils disposed at least partially within the body that are axially aligned with one another with respect to the longitudinal axis through the body, wherein each of the two or more antenna coils, in an unrolled view, has the form of a sinusoidal function that includes a harmonic of order greater than one causing at least one winding of each of the two or more antenna coils to include three or more zero-derivative points, and wherein the longitudinal axis through each of the first slots is perpendicular to a closest one of the three or more zero-derivative points positioned radially-inward therefrom.

10. The logging tool of claim 9, further comprising a plurality of second slots formed radially through the body, wherein a longitudinal axis through each of the second slots is not parallel to the longitudinal axis through the body.

11. The logging tool of claim 10, wherein the longitudinal axis through each of the second slots is perpendicular to a portion of one of the two or more antenna coils positioned radially-inward therefrom.

12. The logging tool of claim 9, wherein a length of one of the first slots is greater than an amplitude of each of the two or more antenna coils.

13. The logging tool of claim 9, wherein one of the first slots is partitioned into first and second portions, wherein the first portion is axially aligned with a closest zero-derivative point of a first of the two or more coils, and wherein the second portion is axially aligned with a closest zero-derivative point of a second of the two or more coils.

14. The logging tool of claim 9, wherein at least one of the three or more zero-derivative points of a first of the two or more coils is axially and rotationally aligned with at least one of the three or more zero-derivative points of a second of the two or more coils.

15. The logging tool of claim 9, wherein at least three of the three or more zero-derivative points of a first of the two or more coils is rotationally aligned with at least three of the three or more zero-derivative points of a second of the two or more coils.

16. A method for manufacturing a logging tool for use in a wellbore, comprising:
forming two or more antenna coils that, in an unrolled view, have the form of sinusoidal functions that include harmonics of order greater than one; and
placing a hollow body at least partially around the two or more antenna coils such that the two or more antenna coils are axially aligned with one another with respect to a longitudinal axis through the body.

17. The method of claim 16, further comprising forming a plurality of first slots radially through the body, wherein a longitudinal axis through each of the first slots is parallel to the longitudinal axis through the body.

18. The method of claim 17, wherein at least one winding of each of the two or more antenna coils includes three or more zero-derivative points, and wherein the longitudinal axis through each of the first slots is perpendicular to a closest one of the three or more zero-derivative points positioned radially inward therefrom.

19. The method of claim 18, further comprising forming a plurality of second slots radially through the body, wherein a longitudinal axis through each of the second slots is not parallel to the longitudinal axis through the body.

20. The method of claim 19, wherein the longitudinal axis through each of the second slots is perpendicular to a portion of one of the two or more antenna coils positioned radially inward therefrom.
